(19) United States
(12) Patent Application Publication
(10) Pub. No.: US 2026/0112570 A1
(43) Pub. Date: Apr. 23, 2026

(54) METHOD FOR MONITORING ELECTRON BEAM OF MEASURING APPARATUS AND MONITORING APPARATUS USING THE SAME

(71) Applicant: United Microelectronics Corp., Hsinchu (TW)

(72) Inventors: Zheng-Yang LI, Kaohsiung City (TW); Li-Hsin Yang, Tainan City (TW); Yu-Chi lin, Taichung City (TW); Zhe-Qi Xu, Singapore (SG)

(21) Appl. No.: 18/919,480

(22) Filed: Oct. 18, 2024

(51) Int. Cl. H01J 37/28

(52) U.S. Cl. CPC H01J 37/28; H01J 2237/2817; H01J 2237/2826

(57) ABSTRACT

A method for monitoring an electron beam of a measuring apparatus and a monitoring apparatus using the same are provided. The monitoring apparatus includes a transmission unit, a controlling unit, a frame analyzing unit, a shift analyzing unit, a determining unit and a warning unit. The controlling unit is configured to transmit a capturing command to the measuring apparatus, for continuously capturing a plurality of electron beam frames of the measuring apparatus, after the measuring apparatus is calibrated. The frame analyzing unit is configured to analyze a density concentration point in each of the electron beam frames. The shift analyzing unit is configured to obtain a largest shift among the density concentration points in the electron beam frames. The warning unit is configured to issue a warning notification to the measuring apparatus, if the largest shift is larger than a predetermined distance.

### TECHNICAL FIELD

The disclosure relates in general to a method for monitoring an apparatus and a monitoring apparatus using the same, and more particularly to a method for monitoring an electron beam of a measuring apparatus and a monitoring apparatus using the same.

### BACKGROUND

In the semiconductor manufacturing process, a measuring apparatus is used to measure the critical dimensions in the semiconductor devices. In order to ensure the accuracy of measurement, the measuring apparatus is calibrated before performing the measurement.

However, some components of the measuring apparatus may be damaged or aged. In this case, the accuracy of the measuring apparatus is worse, even if the measuring apparatus is calibrated.

### SUMMARY

The disclosure is directed to a method for monitoring an electron beam of a measuring apparatus and a monitoring apparatus using the same. After the measuring apparatus is calibrated, the measuring apparatus is monitored via a plurality of electron beam frames of the measuring apparatus. As such, the accuracy of the measuring apparatus could be increased.

According to one embodiment, a method for monitoring an electron beam of a measuring apparatus is provided. The method for monitoring the electron beam of the measuring apparatus includes the following steps: continuously capturing a plurality of electron beam frames of the measuring apparatus, after the measuring apparatus is calibrated; obtaining a density concentration point in each of the electron beam frames; obtaining a largest shift among the density concentration points in the electron beam frames; determining whether the largest shift is larger than a predetermined distance; and issuing a warning notification, if the largest shift is larger than the predetermined distance.

According to an alternative embodiment, a monitoring apparatus is provided. The monitoring apparatus is connected to a measuring apparatus. The monitoring apparatus includes a transmission unit, a controlling unit, a frame analyzing unit, a shift analyzing unit, a determining unit and a warning unit. The transmission unit is connected to the monitoring apparatus. The controlling unit is configured to transmit a capturing command to the measuring apparatus through the transmission unit, for continuously capturing a plurality of electron beam frames of the measuring apparatus, after the measuring apparatus is calibrated. The frame analyzing unit is configured to analyze a density concentration point in each of the electron beam frames. The shift analyzing unit is configured to obtain a largest shift among the density concentration points in the electron beam frames. The determining unit is configured to determine whether the largest shift is larger than a predetermined distance. The warning unit is configured to issue a warning notification to the measuring apparatus through the transmission unit, if the largest shift is larger than the predetermined distance.

### BRIEF DESCRIPTION OF THE DRAWINGS

FIG. 1 shows a measuring apparatus according to one embodiment of the present disclosure.

FIG. 2A shows a plurality of electron beam frames continuously shown in a screen according to one embodiment of the present disclosure.

FIG. 2B shows the electron beam frames continuously shown in the screen according to another embodiment of the present disclosure.

FIG. 3 shows a block diagram of a monitoring apparatus according to one embodiment of the present disclosure.

FIG. 4 shows a flowchart of a method for monitoring an electron beam of a measuring apparatus according one embodiment of the present disclosure.

FIG. 5 illustrates the step S110.

FIG. 6 illustrates the step S130.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

The technical terms used in this specification refer to the idioms in this technical field. If there are explanations or definitions for some terms in this specification, the explanation or definition of this part of the terms shall prevail. Each embodiment of the present disclosure has one or more technical features. To the extent possible, a person with ordinary skill in the art may selectively implement some or all of the technical features in any embodiment, or selectively combine some or all of the technical features in these embodiments.

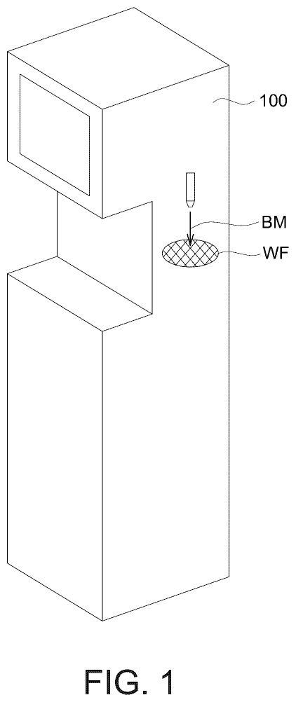

Please refer to FIG. 1, which shows a measuring apparatus 100 according to one embodiment of the present disclosure. In the semiconductor manufacturing process, the measuring apparatus 100 is used to measure the critical dimensions in the semiconductor devices WF through an electron beam BM. For example, the measuring apparatus 100 is a CD-SEM. In order to ensure the accuracy of measurement, the measuring apparatus 100 is calibrated before performing the measurement.

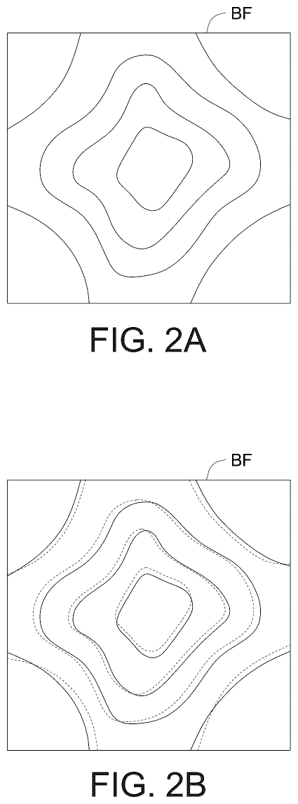

Please refer to FIG. 2A, which shows a plurality of electron beam frames BF continuously shown in a screen according to one embodiment of the present disclosure. Each of the electron beam frames BF is captured from the electron beam BM in the measuring apparatus 100. The electron beam frames BF are continuously captured and continuously shown on the screen. After the measuring apparatus 100 is calibrated, the electron beam BM could be stable and the electron beam frames BF would not be shifted.

Please refer to FIG. 2B, which shows the electron beam frames BF continuously shown in the screen according to another embodiment of the present disclosure. The electron beam frames BF are continuously captured and continuously shown on the screen. In case of some components of the measuring apparatus 100 being damaged or aged, the electron beam BM could not be stable and the electron beam frames BF would be shifted, even if the measuring apparatus 100 is calibrated. Therefore, after the measuring apparatus 100 is calibrated, the measuring apparatus 100 is still needed to be monitored.

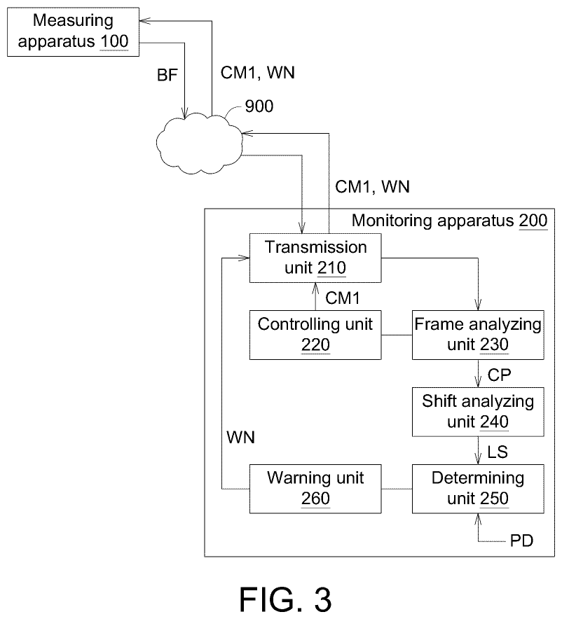

Please refer to FIG. 3, which shows a block diagram of a monitoring apparatus 200 according to one embodiment of the present disclosure. The monitoring apparatus 200 is used to remotely monitor the measuring apparatus 100 after calibrating. The monitoring apparatus 200 includes a transmission unit 210, a controlling unit 220, a frame analyzing unit 230, a shift analyzing unit 240, a determining unit 250 and a warning unit 260. The transmission unit 210 is used to transmit or receive data. For example, the transmission unit 210 is a wireless communication module or a cable network module. The controlling unit 220, the frame analyzing unit 230, the shift analyzing unit 240, the determining unit 250 and the warning unit 260 are used to perform various analyzing procedures, computing procedures or controlling procedures. For example, the controlling unit 220, the frame analyzing unit 230, the shift analyzing unit 240, the determining unit 250 and/or the warning unit 260 is a circuit, a circuit board, a storage device storing program codes or a chip. The chip is, for example, a central processing unit (CPU), a programmable general-purpose or special-purpose micro control unit (MCU), a microprocessor, a digital signal processor (DSP), a programmable controller, an application specific integrated circuit (ASIC), a graphics processing unit (GPU), an image signal processor (ISP), an image processing unit (IPU), an arithmetic logic unit (ALU), a complex programmable logic device (CPLD), an embedded system, a field programmable gate array (FPGA), other similar element or a combination thereof.

The monitoring apparatus 200 is used to remotely monitor the measuring apparatus 100 according to the electron beam frames BF thereof to ensure the accuracy of measurement. The operation of the components of the monitoring apparatus 200 is described via a flowchart as follows.

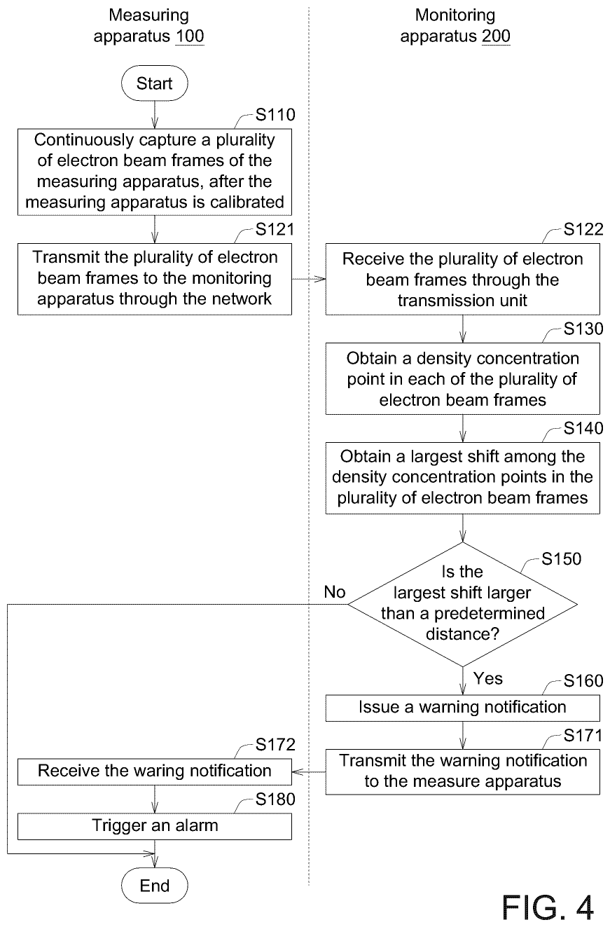

Please refer to FIGS. 3 and 4. FIG. 4 shows a flowchart of a method for monitoring the electron beam BM of the measuring apparatus 100 according one embodiment of the present disclosure. The method includes steps 110, S121, S122, S130 to S160, S171, S172 and S180.

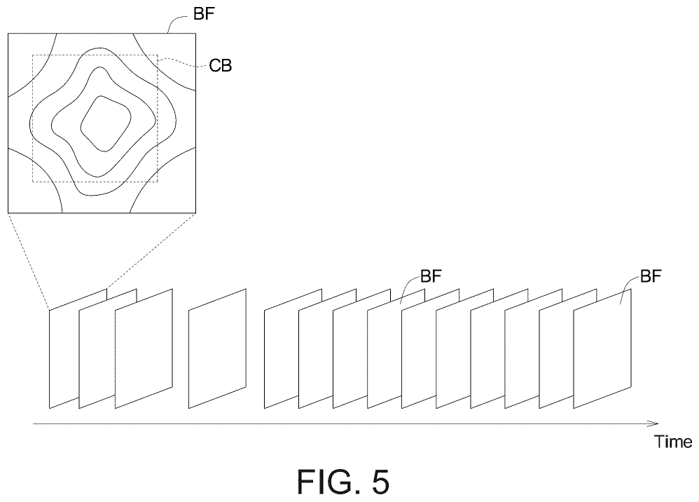

Please refer to FIG. 5, which illustrates the step S110. In the step S110, as shown in the FIGS. 3 and 5, the plurality of electron beam frames BF of the measuring apparatus 100 are continuously captured, after the measuring apparatus 100 is calibrated. In this step, when the measuring apparatus 100 is calibrated, the controlling unit 220 of the monitoring apparatus 200 transmits a capturing command CM1 to the measuring apparatus 100. Then, the measuring apparatus 100 automatically turns on the electron beam BM and captures the plurality of electron beam frames BF for a predetermined time period, such as 1 second. A quality of the electron beam frames BF is, for example, 50 to 80. The electron beam frames BF are, for example, taken at equal intervals. In one embodiment, a quality of the electron beam frames BF is inversely proportional to a minimum shooting shutter, and directly proportional to a shaking period of the electron beam BM.

Next, in the step S121, as shown in the FIG. 3, the plurality of electron beam frames BF are transmitted to the monitoring apparatus 200 through the network 900.

Then, in the step S122, as shown in the FIG. 3, the frame analyzing unit 230 receives the plurality of electron beam frames BF through the transmission unit 210.

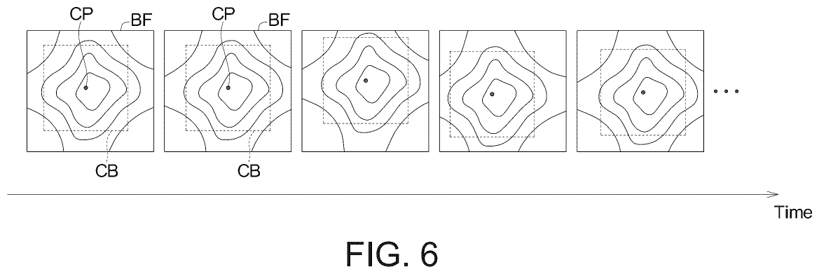

Afterwards, please refer to FIG. 6, which illustrates the step S130. In the step S130, as shown in the FIGS. 3 and 6, the frame analyzing unit 230 obtains a density concentration point CP in each of the electron beam frames BF. In this step, the density concentration point CP in each of the electron beam frames FM is obtained via a K-means algorithm, a DBSscan algorithm or a Meanshift algorithm. As shown in the FIG. 6, the frame analyzing unit 230 recognizes a density concentration box CB in each of the electron beam frames BF and then defines a center point of each of the density concentration boxes CB as the density concentration point CP.

Next, in the step S140, as shown in the FIG. 3, the shift analyzing unit 240 obtains a largest shift LS among the density concentration points CP in the electron beam frames BF. In one embodiment, the largest shift LS is the largest one among the shifts of all of the density concentration points CP. Or, the largest shift LS is the largest one among the shifts between the two density concentration points CP of any two adjacent electron beam frames.

Then, in the S150, as shown in the FIG. 3, the determining unit 250 determines whether the largest shift LS is larger than a predetermined distance PD. If the largest shift LS is larger than the predetermined distance PD, the process proceeds to the step S160.

In the step S160, as shown in the FIG. 3, the warning unit 260 issues a warning notification WN.

Next, in the step S171, as shown in the FIG. 3, the transmitting unit 210 transmits the warning notification WN to the measure apparatus 100.

Then, in the step S172, as shown in the FIG. 3, the measuring apparatus 100 receives the waring notification WN.

Next, in the step S180, as shown in the FIG. 3, the measuring apparatus 100 triggers an alarm to notify the user that the electron beam BM of the measuring apparatus 100 is unstable and needed to be repaired.

According to the embodiments described above, the monitoring apparatus 200 could remotely monitor the measuring apparatus 100 according to the electron beam frames BF thereof to ensure the accuracy of measurement.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. A method for monitoring an electron beam of a measuring apparatus, comprising:
continuously capturing a plurality of electron beam frames of the measuring apparatus, after the measuring apparatus is calibrated;
obtaining a density concentration point in each of the electron beam frames;
obtaining a largest shift among the density concentration points in the electron beam frames;
determining whether the largest shift is larger than a predetermined distance; and
issuing a warning notification, if the largest shift is larger than the predetermined distance.

2. The method for monitoring the electron beam of the measuring apparatus according to claim 1, wherein the measuring apparatus is a CD-SEM.

3. The method for monitoring the electron beam of the measuring apparatus according to claim 1, wherein the density concentration point in each of the electron beam frames is obtained via a K-means algorithm, a DBSscan algorithm or a Meanshift algorithm.

4. The method for monitoring the electron beam of the measuring apparatus according to claim 1, wherein a quality of the electron beam frames is 50 to 80.

5. The method for monitoring the electron beam of the measuring apparatus according to claim 1, wherein a quality of the electron beam frames is inversely proportional to a minimum shooting shutter, and directly proportional to a shaking period of the electron beam.

6. The method for monitoring the electron beam of the measuring apparatus according to claim 1, wherein the electron beam frames are captured in one second.

7. The method for monitoring the electron beam of the measuring apparatus according to claim 1, wherein the electron beam frames are taken at equal intervals.

8. The method for monitoring the electron beam of the measuring apparatus according to claim 1, wherein the warning notification is transmitted via network.

9. The method for monitoring the electron beam of the measuring apparatus according to claim 1, wherein the density concentration point in each of the electron beam frames is a center point of a density concentration box.

10. A monitoring apparatus, connected to a measuring apparatus, wherein the monitoring apparatus comprises:
a transmission unit, connected to the monitoring apparatus;
a controlling unit, configured to transmit a capturing command to the measuring apparatus through the transmission unit, for continuously capturing a plurality of electron beam frames of the measuring apparatus, after the measuring apparatus is calibrated;
a frame analyzing unit, configured to analyze a density concentration point in each of the electron beam frames;
a shift analyzing unit, configured to obtain a largest shift among the density concentration points in the electron beam frames;
a determining unit, configured to determine whether the largest shift is larger than a predetermined distance; and
a warning unit, configured to issue a warning notification to the measuring apparatus through the transmission unit, if the largest shift is larger than the predetermined distance.

11. The monitoring apparatus according to claim 10, wherein the measuring apparatus is a CD-SEM.

12. The monitoring apparatus according to claim 10, wherein the density concentration point in each of the electron beam frames is obtained via a K-means algorithm, a DBSscan algorithm or a Meanshift algorithm.

13. The monitoring apparatus according to claim 10, wherein a quality of the electron beam frames is 50 to 80.

14. The monitoring apparatus according to claim 10, wherein a quality of the electron beam frames is inversely proportional to a minimum shooting shutter, and directly proportional to a shaking period of the electron beam.

15. The monitoring apparatus according to claim 10, wherein the electron beam frames are captured in one second.

16. The monitoring apparatus according to claim 10, wherein the electron beam frames are taken at equal intervals.

17. The monitoring apparatus according to claim 10, wherein the warning notification is transmitted via network.

18. The monitoring apparatus according to claim 10, wherein the density concentration point in each of the electron beam frames is a center point of a density concentration box.
